(19) United States
(12) Patent Application Publication
(10) Pub. No.: US 2018/0086973 A1
(43) Pub. Date: Mar. 29, 2018

(54) PHOSPHOR AND LIGHT-EMITTING DEVICE

(71) Applicant: Denka Company Limited, Tokyo (JP)

(72) Inventors: Ryosuke KONDO, Fukuoka (JP); Masayoshi ICHIKAWA, Fukuoka (JP); Hideyuki EMOTO, Fukuoka (JP); Motoi TANAKA, Tokyo (JP)

(21) Appl. No.: 15/544,679

(22) PCT Filed: Jan. 19, 2016
(86) PCT No.: PCT/JP2016/051443

§ 371 Date: Dec. 11, 2017

(30) Foreign Application Priority Data
Jan. 20, 2015 (JP) 2015-008208

(51) Int. Cl. C09K 11/02; C09K 11/61; H01L 33/50

(52) U.S. Cl. CPC C09K 11/025; H01L 33/502; C09K 11/617

(57) ABSTRACT

Provided is a phosphor that emits red light, is represented by the general formula, A₂MF₆:Mn, and exhibits little reduction in intensity even when exposed to a high-temperature, high-humidity atmosphere over a long period of time. Also provided is a light-emitting device using said phosphor. The present invention is a phosphor in which the main crystal phase thereof is represented by the general formula, A₂MF₆:Mn. The element A is an alkali metal element including at least K, and the element M is one or more tetravalent elements selected from the group consisting of Si, Ge, Sn, Ti, Zr, and Hf. The phosphor has a coating layer on the surface thereof. The coating layer is a hydrophobic organic substance having a hydrophobicity of 10% or more.

### TECHNICAL FIELD

The present invention relates to a phosphor that emits red light when excited with blue light and a light emitting device having the phosphor.

### BACKGROUND ART

Patent Document 1 discloses a red light emitting phosphor represented by the general formula: A₂MF₆:Mn⁴⁺.

When exposed to an atmosphere at high temperature and high humidity for a long time, the phosphor has caused a problem that emission intensity of the phosphor itself has been decreased. The decrease in the emission intensity of the phosphor would cause a decrease in luminance of an LED using the phosphor and a change of luminescent color.

The problem might be solved by a surface coating as described in Patent Document 2.

However, the phosphor represented by the general formula A₂MF₆:Mn cannot be subjected to simple surface coating or surface treatment with water, because the phosphor itself is soluble in hydrogen fluoride or water.

### CITATION LIST

### Patent Literature

Patent Document 1: Japanese Patent Application Laid-open Publication No. 2009-528429 A1

Patent Document 2: Japanese Patent Application Laid-open Publication No. 2002-322473 A1

Non-Patent Document 1: A. G. Paulusz, Journal of The Electrochemical Society, 1973, vol. 120, No. 7, p. 942-947

### SUMMARY OF THE INVENTION

### Technical Problem

An object of the present invention is to provide a red light emitting phosphor represented by the general formula: A₂MF₆:Mn, which can suppress a decrease in emission intensity even if the phosphor is exposed to an atmosphere at high temperature and high humidity, and a light emitting device using the phosphor.

### Solution to Problem

The present invention relates to a phosphor comprising a main crystal phase represented by the general formula: A₂MF₆:Mn in which the elements A each represents at least one alkali metal element including at least K, and the element M represents one or more tetravalent elements selected from the group consisting of Si, Ge, Sn, Ti, Zr and Hf, the phosphor having a coating layer on a surface of the phosphor, the coating layer comprising an organic substance having a degree of hydrophobicity of 10% or more.

The organic substance may be preferably a fatty acid.

The fatty acid may be preferably a long chain fatty acid.

The present invention relates to a light emitting device comprising the phosphor and a light emitting element.

### DESCRIPTION OF EMBODIMENTS

The present invention relates to a phosphor comprising a main crystal phase represented by the general formula: A₂MF₆:Mn in which the elements A each represents at least one alkali metal element including at least K, and the element M is one or more tetravalent elements selected from the group consisting of Si, Ge, Sn, Ti, Zr and Hf, the phosphor having a coating layer on the surface of the phosphor, the coating layer comprising an organic substance having a degree of hydrophobicity of 10% or more.

The element A may be at least one alkali metal element including at least K, and more particularly K alone, K and Li, K and Na, K and Rb, or K and Cs, and preferably K alone.

The element M may be one or more metal elements selected from Si, Ge, Sn, Ti, Zr, and Hf, and more particularly Si alone, Ge alone, Si and Ge, Si and Sn, or Si and Ti, and preferably Si alone.

The F is fluorine and the Mn is manganese.

The organic substance forming the coating layer of the phosphor according to the present invention may have a degree of hydrophobicity of 10% or more, and preferably 30% or more, and more preferably 50% or more. Specifically, the organic substance may be a fatty acid. The phosphor comprising the organic substance having the hydrophobic property as the coating layer can provide high stability to water and can suppress a decrease in emission intensity even if the phosphor is exposed to an atmosphere at high temperature and high humidity.

The degree of hydrophobicity was measured by the following method:

(1) 0.2 g of the phosphor to be measured was weighed in a 500 ml Erlenmeyer flask;

(2) 50 ml of ion exchanged water was added to the Erlenmeyer flask (1) and stirred with a stirrer;

(3) methanol was dropped from a burette with stirring, and when the whole amount of the phosphor was suspended in ion exchanged water the amount of dropped methanol was measured;

(4) the degree of hydrophobicity was calculated by the following equation:

Degree of hydrophobicity (%)=(dropped methanol amount (ml))×100/(dropped methanol amount (ml)+ion exchange water amount (ml))

Examples of the fatty acid may include short chain fatty acids having 2 to 4 carbon atoms, medium chain fatty acids having 5 to 11 carbon atoms, and long chain fatty acids having 12 or more carbon atoms. The long chain fatty acids may be preferable, more preferably including oleic acid, lauric acid, stearic acid, behenic acid, myristic acid, erucic acid and linoleic acid.

The content of the organic substance may be preferably 1.0% by mass or more and 5.0% by mass or less relative to 100% by mass of the phosphor. If the amount of the organic substance is too low, it will be difficult to produce the effect of stabilization to water which will be obtained by coating of the organic substance. If the amount of the organic substance is too high, curing of a resin near the surface of the phosphor will be inhibited, resulting in color shift of the phosphor due to a change over time.

The thickness of the coating layer of the phosphor may preferably be 0.02 μm or more and 0.5 μm or less.

The present invention also relates to a light emitting device comprising the phosphor as stated above and a light emitting element. Examples of the light emitting device include illuminating devices, backlight for liquid crystal panels, signal devices, and light sources for projectors.

When the phosphor according to the present invention is mounted on a light emitting surface of the LED, the phosphor is mixed in an amount of 30% by mass or more and 50% by mass or less with a thermosetting resin having fluidity at normal temperature before mounting the phosphor. Examples of the thermosetting resin may include silicone resins, more particularly JCR 6175 available from Dow Corning Toray Co., Ltd.

A₂MF₆:Mn that is the phosphor according to the present invention absorbs excitation light in a wavelength range of 420 nm or more and 480 nm or less received from the LED and emits light in a range of more than 600 nm and 650 nm or less.

### EXAMPLE

### Comparative Example 1

The phosphor according to the present invention is formed by laminating a coating layer onto a conventional phosphor. Therefore, the conventional phosphor is referred to as Comparative Example 1. The phosphor of Comparative Example 1 will be described.

The phosphor of Comparative Example 1 is represented by the general formula: K₂SiF₆:Mn, in which the element A is K, and the element M is Si. A method for producing the phosphor will be described. The method is composed of a solution preparation step, a precipitation step, a washing step and a classification step.

“Solution Preparation Step”

At normal temperature, 100 ml of hydrofluoric acid having a concentration of 55% by mass (available from Stella Chemifa Corporation) was placed in a 500 ml Teflon® beaker, and 3 g of K₂SiF₆ powder (available from MORITA CHEMICAL INDUSTRIES, CO., LTD.) and 0.5 g of K₂MnF₆ powder prepared in the next producing step were added to the beaker and dissolved to prepare a solution.

<Producing Step of K₂MnF₆>

K₂MnF₆ was produced using the producing step described in Non-Patent Document 1, specifically as follows:

80 ml of hydrofluoric acid having a concentration of 40% by mass was placed in a one-liter Teflon® beaker, and 260 g of KHF₂ powder (available from Wako Pure Chemical Industries, Ltd., special grade reagent) and 12 g of potassium permanganate powder (available from Wako Pure Chemical Industries, Ltd., first class grade reagent) were added to the beaker and dissolved.

8 ml of 30% hydrogen peroxide water (special grade reagent) was gradually added dropwise while stirring the hydrofluoric acid reaction solution with a magnetic stirrer.

Once a dropping amount of hydrogen peroxide solution exceeded a predetermined amount, K₂MnF₆ began to be separated and the color of the reaction solution began to change from purple.

After a certain amount of aqueous hydrogen peroxide was added dropwise, the stirring was continued for a certain period of time, and the stirring was then stopped to precipitate K₂MnF₆.

After precipitation of K₂MnF₆, a supernatant was removed, methanol was added, stirred and allowed to stand, a supernatant was removed, and methanol was further added, and the procedures were repeated until a neutral solution was obtained.

K₂MnF₆ was then recovered by filtration and further dried to completely remove methanol by evaporation to yield 19 g of K₂MnF₆. K₂MnF₆ was in the form of powder.

All these operations were carried out at normal temperature.

“Precipitation Step”

150 ml of water was added to the solution after the solution preparation step and stirred for 10 minutes. After stirring, the mixture was allowed to stand to precipitate a solid. The solid was a phosphor. By adding water to the solution, the saturation concentration of the fluoride phosphor represented by the above formula would be changed, thereby precipitating the phosphor.

“Washing Step”

After removing the supernatant of the solution after the separation step, washing was carried out with 20% by mass of hydrofluoric acid, followed by methanol. The purpose of the washing with methanol was to remove the remaining of hydrofluoric acid.

After washing, the solid was separated and recovered by filtration. The remaining methanol used in the washing was then dried and removed.

“Classification Process”

The classification step was carried out for suppressing variations in the particle size of the phosphor and adjusting the particle size within a certain range. More specifically, in the classification step, the phosphor powder was classified into one which passed through a sieve having an opening with a predetermined size and other which did not passed through the sieve. Using a nylon sieve having a mesh opening of 75 μm, only the phosphor passed through the sieve was collected to finally obtain 1.3 g of K₂SiF₆:Mn phosphor. The phosphor is referred to as Comparative Example 1.

### Example 1

The phosphor of Example 1 was obtained by laminating oleic acid as a material for the coating layer having a thickness of 0.04 μm on the surface of the phosphor of Comparative Example 1. Oleic acid is a long chain fatty acid having 18 carbon atoms.

The coating layer was laminated by mixing the phosphor of Comparative Example 1 with oleic acid (KANTO CHEMICAL CO., INC., first class grade guaranteed by KANTO CHEMICAL) for 10 minutes. The mixing was carried out at a mixing ratio of 100% by mass of the phosphor of Comparative Example 1 and 1.0% by mass of oleic acid. The phosphor after mixing was passed through a sieve having a mesh opening of 75 μm to recover only the phosphor passed through the sieve. The thickness of the oleic acid coating layer can be adjusted by varying the mass percent of oleic acid during the mixing.

Evaluations of the phosphors of Examples and Comparative Example 1 are listed in Table 1.

TABLE 1

| | | | | EXAMPLES | | | | | | | |
|---|---|---|---|---|---|---|---|---|---|---|---|
| | | | | 1 | 2 | 3 | 4 | 5 | 6 | 7 | COMP. 1 |
| Coating | Oleic Acid | | | 0.04 | 0.12 | 0.20 | — | — | — | — | — |
| Thickness | Lauric Acid | | | — | — | — | 0.04 | — | — | — | — |
| of | Stearic Acid | | | — | — | — | — | 0.04 | — | — | — |
| Coating | Behenic Acid | | | — | — | — | — | — | 0.04 | — | — |
| Layer | Erucic Acid | | | — | — | — | — | — | — | 0.04 | — |
| (μm) | | | | | | | | | | | |
| Evaluation | Degree of Hydrophobicity (%) | | | 75 | 86 | 91 | 75 | 78 | 75 | 82 | 0 |
| | Internal Quantum Efficiency (%) | | | 81.2 | 79.7 | 78.6 | 78.2 | 77.4 | 78.8 | 75.5 | 79.5 |
| | External Quantum Efficiency (%) | | | 61.3 | 59.5 | 59.2 | 59.0 | 57.5 | 58.9 | 58.6 | 60.2 |
| | Chromaticity CIEx | | | 0.691 | 0.692 | 0.693 | 0.690 | 0.692 | 0.691 | 0.689 | 0.689 |
| | Chromaticity CIEy | | | 0.307 | 0.307 | 0.306 | 0.307 | 0.306 | 0.305 | 0.308 | 0.308 |
| | External Quantum | Drive | 0 | 100 | 100 | 100 | 100 | 100 | 100 | 100 | 100 |
| | Efficiency Retention | Time | 25 | 95.8 | 97.2 | 96.6 | 94.2 | 95.4 | 96.3 | 99.0 | 79.1 |
| | Rate (%) | (hr) | | | | | | | | | |

“Coating Thickness of Coating Layer” in Table 1 shows the “organic substance having hydrophobicity” used as the coating layer for each phosphor of Examples and its coating thickness value. The unit of the coating thickness value is μm. For Comparative Example 1, no coating layer is provided and no value is thus given.

Oleic acid is a long chain fatty acid having 18 carbon atoms, lauric acid is a long chain fatty acid having 12 carbon atoms, stearic acid is a long chain fatty acid having 18 carbon atoms, and behenic acid and erucic acid are long chain fatty acids having 22 carbon atoms.

The coating thickness of each coating layer was calculated from the following equation:

Coating Thickness (μm)=(Volume of Coating layer (m³)/Surface Area of Phosphor (m²))×10⁶.

Volume (m³) of Coating Layer=Coating Layer (g)/(Density of Coating Layer (g/cm³)×10⁶.

Surface Area of Phosphor (m²)=Specific Surface area of Phosphor (m²/g)×Total Phosphor Mass (g).

For the evaluation in Table 1, the degree of hydrophobicity was as described above, and others were evaluated as follows:

<Internal Quantum Efficiency and External Quantum Efficiency>

The internal quantum efficiency and external quantum efficiency were measured using a spectrophotometer (MCPD-7000 available from OTSUKA ELECTRONICS Co., Ltd.). Blue light with a wavelength of 455 nm was used as excitation light.

A sample portion of the spectrophotometer was filled with the phosphor to be measured, a standard reflector having a reflectance of 99% (Spectralon available from Labsphere) was set, and a spectrum of excitation light was measured. Qex (the number of excitation light photons) was calculated from the spectrum in the wavelength range of 450 nm to 465 nm.

The phosphor to be measured was set in the sample portion, and Qref (the number of excitation reflected light photons) and Qem (the number of fluorescence photons) were calculated from the resulting spectrum data. Qref was calculated in the same wavelength range as that of Qex, and Qem was calculated in a wavelength range of 465 nm to 800 nm.

Based on the numbers of photons, the internal quantum efficiency and the external quantum efficiency were calculated by the following equations:

Internal Quantum Efficiency (=Qem/(Qex−Qref)×100)

External Quantum Efficiency (=Qem/Qex×100).

<Chromaticity Coordinates CIEx and CIEy>

Measurement was carried out using a spectrophotometer (MCPD-7000 available from OTSUKA ELECTRONICS Co., Ltd.). Blue light with a wavelength of 455 nm was used as excitation light.

A sample portion of the spectrophotometer was filled with the phosphor to be measured, the surface of the phosphor was smoothed, and an integrating sphere was attached. In the integrating sphere, monochromic light obtained by dispersing light from a Xe lamp as a light source to blue light having a wavelength of 455 nm was introduced through an optical fiber. The measurement was carried out by irradiating the phosphor with the monochromatic light. Chromaticity coordinates CIEx and CIEy in the XYZ color coordinate system defined in JIS Z8701 according to JIS Z8724 were calculated from the data of the wavelength range from 465 nm to 780 nm among the measurement results.

<External Quantum Efficiency Retention Rate>

The external quantum efficiency was measured using a spectrophotometer (MCPD-7000 available from OTSUKA ELECTRONICS Co., Ltd.).

The external quantum efficiency retention rate in Table 1 was determined by leaving the phosphor to be measured for 25 hours in an environment at a temperature of 60° C. and humidity of 90%, then measuring the external quantum efficiency of the phosphor, dividing the external quantum efficiency after being left for 25 hours by the “external quantum efficiency before exposure” and multiplying the resulting value by 100. The acceptable value for the external quantum efficiency retention rate is 85%.

The phosphor of Example 1 had a degree of hydrophobicity of 75%. The internal quantum efficiency, the external quantum efficiency, the chromaticity CIE x, the chromaticity CIE y and the relative peak intensity in Example 1 were substantially the same values as those of Comparative Example 1. The external quantum efficiency retention rate in Example 1 was a higher value than that of Comparative Example 1, that is, 95.8% as compared with 79.1% in Comparative Example 1.

### Examples 2 to 8

Each of the phosphors of Examples 2 to 8 was produced by the same method as that of Example 1, with the exception that the material and coating thickness of the coating layer of the phosphor of Example 1 was changed as shown in Table 1.

The phosphors of Examples 2 and 3 were obtained by laminating oleic acid under the same conditions as that of Example 1, with the exception that 1.0% by mass of oleic acid used in the lamination step of the coating layer in Example 1 was changed to 3.0% by mass for Example 2 and 5.0% by mass for Example 3, and as a result, only the coating thickness of the phosphor of Example 1 was changed to 0.12 μm for Example 2 and 0.20 μm for Example 3.

The phosphor of Example 4 was obtained by laminating the coating layer under the same conditions as those of Example 1, with the exception that 1.0% by mass of oleic acid used in the lamination step of the coating layer in Example 1 was changed to 1.0% by mass of “lauric acid diluted with ethanol (available from KANTO CHEMICAL CO., INC.)”. Lauric acid is a long chain fatty acid having 12 carbon atoms.

The phosphor of Example 5 was obtained by laminating the coating layer under the same conditions as those of Example 1, with the exception that 1.0% by mass of oleic acid used in the lamination step of the coating layer in Example 1 was changed to 1.0% by mass of “stearic acid diluted with ethanol (available from Tokyo Chemical Industry Co., Ltd.)”. Stearic acid is a long chain fatty acid having 18 carbon atoms.

The phosphor of Example 6 was obtained by laminating the coating layer under the same conditions as those of Example 1, with the exception that 1.0% by mass of oleic acid used in the lamination step of the coating layer in Example 1 was changed to 1.0% by mass of “behenic acid diluted with ethanol (available from KANTO CHEMICAL CO., INC.)”. Behenic acid is a long chain fatty acid having 22 carbon atoms.

The phosphor of Example 7 was obtained by laminating the coating layer under the same conditions as those of Example 1, with the exception that 1.0% by mass of oleic acid used in the lamination step of the coating layer in Example 1 was changed to 1.0% by mass of erucic acid (available from KANTO CHEMICAL CO., INC.). Erucic acid is a long chain fatty acid having 22 carbon atoms.

In Example 8, a light emitting device was produced in which the phosphor of Example 1 was mounted on the light emitting surface of the LED, although not shown in Table 1. Specifically, the light emitting device of Example 8 was a white light emitting illumination device. The light emitting device of Example 8 had decreased change over time, because the device employed the phosphor of Example 1.

1. A phosphor comprising a main crystal phase represented by the general formula: A₂MF₆:Mn in which the elements A each represents at least one alkali metal element including at least K, and the element M represents one or more tetravalent elements selected from the group consisting of Si, Ge, Sn, Ti, Zr and Hf, the phosphor having a coating layer on a surface of the phosphor, the coating layer comprising an organic substance having a degree of hydrophobicity of 10% or more.

2. The phosphor according to claim 1, wherein the organic substance is a fatty acid.

3. The phosphor according to claim 2, wherein the fatty acid is a long chain fatty acid.

4. A light emitting device comprising the phosphor according to claim 1 and a light emitting element.

5. The light emitting device according to claim 4, wherein the organic substance is a fatty acid.

6. The light emitting device according to claim 5, wherein the fatty acid is a long chain fatty acid.
